(19) United States
(12) Patent Application Publication
(10) Pub. No.: US 2016/0380172 A1
(43) Pub. Date: Dec. 29, 2016

(54) COMPONENT ARRANGEMENT AND METHOD FOR PRODUCING A COMPONENT ARRANGEMENT

(71) Applicant: OSRAM OPTO SEMICONDUCTORS GMBH, Regensburg (DE)

(72) Inventors: Michael Brandl, Mintraching (DE); Stefan Groetsch, Bad Abbach (DE); Tobias Gebuhr, Regensburg (DE); Michael Zitzlsperger, Regensburg (DE); Thomas Schwarz, Regensburg (DE)

(73) Assignee: OSRAM OPTO SEMICONDUCTORS GMBH, Regensburg (DE)

(21) Appl. No.: 15/039,861

(22) PCT Filed: Nov. 25, 2014
(86) PCT No.: PCT/EP2014/075554

§ 371 Date: May 27, 2016

(30) Foreign Application Priority Data
Nov. 28, 2013 (DE) 10 2013 113 185.9
May 12, 2014 (DE) 10 2014 208 903.4

(51) Int. Cl. H01L 33/62; F21S 8/10; H01L 25/075

(52) U.S. Cl. CPC H01L 33/62; H01L 25/0753; F21S 48/115; F21S 48/215

(57) ABSTRACT

Various embodiments may relate to a component arrangement with at least two electrical components arranged next to one another in a product configuration. Each of the electrical components have at least two electrical terminal contacts and the components arranged next to one another are mechanically connected to one another by an adhesive arranged between the components, and the component arrangement is designed for the individual components of the component arrangement to be applied together to a circuit carrier.

### RELATED APPLICATIONS

The present application is a national stage entry according to 35 U.S.C. §371 of PCT application No.: PCT/EP2014/075554 filed on Nov. 25, 2014, which claims priority from German application Nos.: 10 2013 113 185.9 filed on Nov. 28, 2013, and 10 2014 208 903.4 filed on May 12, 2014, and is incorporated herein by reference in its entirety.

### TECHNICAL FIELD

Various embodiments generally relate to a component arrangement. The component arrangement includes at least two electrical components. A method for producing an electrical component arrangement is also described.

### BACKGROUND

In the production of electrical subassemblies, generally a large number of electrical components are applied to a circuit carrier, such as for example a printed circuit board. When applying the components, minimum spacings between the individual components have to be maintained, for example because of production tolerances and the application accuracy of the component insertion machines. The minimum spacings limit the packing density of the components on the circuit carrier. Since particularly high-value circuit carriers, such as for example metal-core printed circuit boards, are relatively expensive, efforts are being made to reduce the minimum spacings, and thereby increase the packing density of the components on the circuit carrier.

The application of a large number of components is also time-consuming, since the components generally have to be individually picked up by an insertion head of a component insertion machine and placed at a desired position on a circuit carrier.

Optoelectronic components with two or more LED chips are known for example from the related art. In general, this type of construction can be referred to as a multi-chip component. Although multi-chip components allow a high packing density, in the case of this type of construction the number and arrangement of the LED chips of the component are fixed in advance. For different optoelectronic applications, however, often different arrangements of the components are desired. Apart from restrictions with regard to the arrangement of the components, the production costs for multi-chip components are also generally higher than for comparable individual components.

One problem that is addressed is consequently that of providing the electrical components in such a way that the electrical components can be easily processed and can be applied to a circuit carrier with small minimum spacings. A corresponding production method is also to be provided.

### SUMMARY

To solve this problem, a component arrangement with at least two electrical components arranged next to one another in a product configuration is proposed. Each of the at least two electrical components has at least two electrical terminal contacts. The components arranged next to one another are mechanically connected to one another by an adhesive arranged between the components, and the component arrangement is designed for the individual components of the component arrangement to be applied together to a circuit carrier.

Since the electrical components in the component arrangement can be handled like a single component, a number of components can be quickly applied to a circuit carrier during subassembly production. Since the individual components of the component arrangement are rigidly connected to one another by the adhesive, the components of the component arrangement can be applied to the circuit carrier with high precision in relation to one another. In this way, the minimum spacings between the individual components of the component arrangement can be reduced.

Moreover, product-specific multiple components can be provided by the component arrangement. For example, generic individual components can be combined in a product-specific component arrangement. For example, the manufacturer of the components or a system supplier can fabricate the components in a product configuration prescribed by the customer, for example a manufacturer of electronic subassemblies. A customer can procure and process the component arrangement instead of a large number of individual components. This allows the effort involved for the customer in terms of the logistics and processing of the components to be reduced. Instead of a large number of individual components, only the component arrangement has to be handled. In comparison with multi-chip components, the components can be provided more easily by a manufacturer of the component, since no special forms of construction of the component or special elements are required for the different arrangements of the components.

The problem is also solved by proposing a method for producing a component arrangement. The method includes providing at least two electronic components and a processing carrier having an adhesive layer, arranging the at least two components on the adhesive layer of the processing carrier in a product configuration, mechanically connecting the components with an adhesive, removing the component arrangement from the processing carrier, and packing the component arrangement in a transport packaging.

The at least two electrical components may be optoelectronic components that are designed for emitting electromagnetic radiation. For example, the electrical components may be light-emitting diodes. The component arrangement may exclusively contain optoelectronic components. The component arrangement may have at least two identical components. The component arrangement may also have at least two different components. A component arrangement may have a first number of a first component and a second number of a second component. A component arrangement may have identical and/or different components.

The product configuration may correspond to an arrangement of the at least two components in an end product. The spacings between the individual components of the component arrangement may correspond to the spacings of the components in an end product. In particular in the case of optoelectronic components, the product configuration may be relevant for the function of the end product. The product configuration may be customer-specific.

The at least two electrical terminal contacts of a component may be designed for the component to be electrically connected to terminal contacts of a circuit carrier by means of a soldering or adhesive-bonding process. The terminal contacts of a circuit carrier may for example be solder pads. The terminal contacts of the component may also be intended to connect the component mechanically or thermally to the circuit carrier by means of a soldering or adhesive-bonding process. Solder beads may be arranged at the electrical terminal contacts of the electrical components. The solder beads may be designed for connecting the electrical terminal contacts of the component in a mechanical and electrically conducting manner to terminal contacts of a circuit carrier by means of a soldering process.

The components arranged in the component arrangement may have a single light-emitting chip. In addition to the light-emitting chip, the component may contain further functional elements. For example, an ESD protection diode may be integrated in the component. The component may have a substrate or a leadframe. The component may have a phosphor. The components of the component arrangement may respectively have a separate housing. The components may be designed for being applied individually to a circuit carrier by means of surface mounting.

The components of the component arrangement may be designed for being activated independently of one another. There may be no direct electrically conducting connections between the individual components of the component arrangement.

The adhesive may be electrically insulating. The adhesive may be designed for being removed during and/or after the application of the component arrangement to a circuit carrier. The mechanical strength of the adhesive may be less in the installed state than in the uninstalled state. The adhesive may be chosen such that the mechanical strength of the cured adhesive can be reduced by a processing step. The mechanical strength of the adhesive in the installed state of the component arrangement may be less than the mechanical strength of a component.

The spacing between two adjacently arranged components may be less than 200 μm. For example, the spacing between two adjacent components may be less than or equal to 100 μm. The spacing between two adjacent components may also be less than or equal to 50 μm.

The component arrangement may be a fabricated unit with for example 20 components. The 20 components are arranged in a product configuration. In the product configuration, the spacings and/or positional tolerances may be less than in the case of individually inserted components. For example, the components of the component arrangement may be respectively arranged with a spacing of 50 pm and a tolerance of approximately +/−15 μm.

For the mechanical connection of the components, the adhesive may for example be introduced between the components by means of dispensing. The adhesive may be introduced between the components before or after the arrangement of the components on the processing carrier. For example, the adhesive may be applied to a side face of the component before the arrangement of the component on the processing carrier. The adhesive may also be introduced between the components after the arrangement of at least two components on the processing carrier. After the introduction of the adhesive, the adhesive may be cured.

Solder beads may be attached to the terminal areas of the components after the removal of the component arrangement from the processing carrier.

### BRIEF DESCRIPTION OF THE FIGURES

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1A shows a schematic representation of a plan view of a single component;

FIG. 1B shows a schematic representation of a cross section of the component represented in FIG. 1A;

FIG. 1C shows a schematic representation of a cross section of a single component;

FIG. 1D shows a schematic representation of a plan view of the component represented in FIG. 1C;

FIG. 2A shows a schematic representation of a plan view of a component arrangement;

FIG. 2B shows a schematic representation of a cross section of a component arrangement;

FIG. 2C shows a schematic representation of a plan view of a component arrangement;

FIG. 3 shows a schematic representation of a cross section of an assembled subassembly; and

FIG. 4 shows a schematic representation of a plan view of a component arrangement.

### DETAILED DESCRIPTION

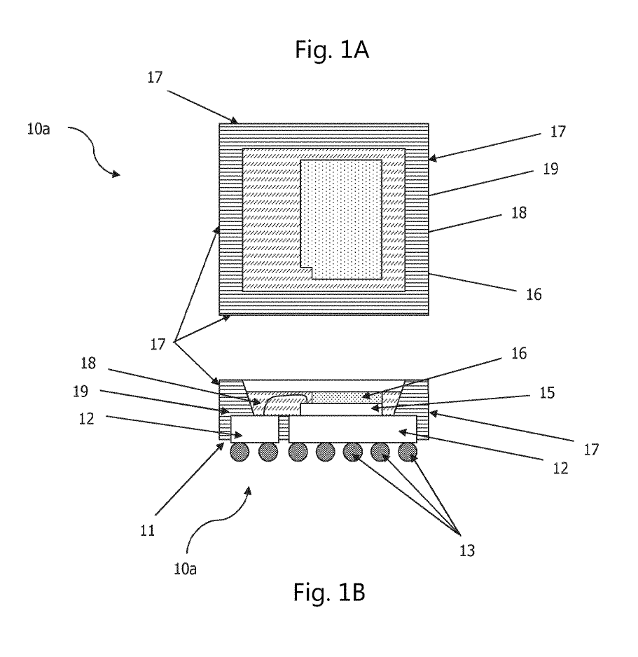

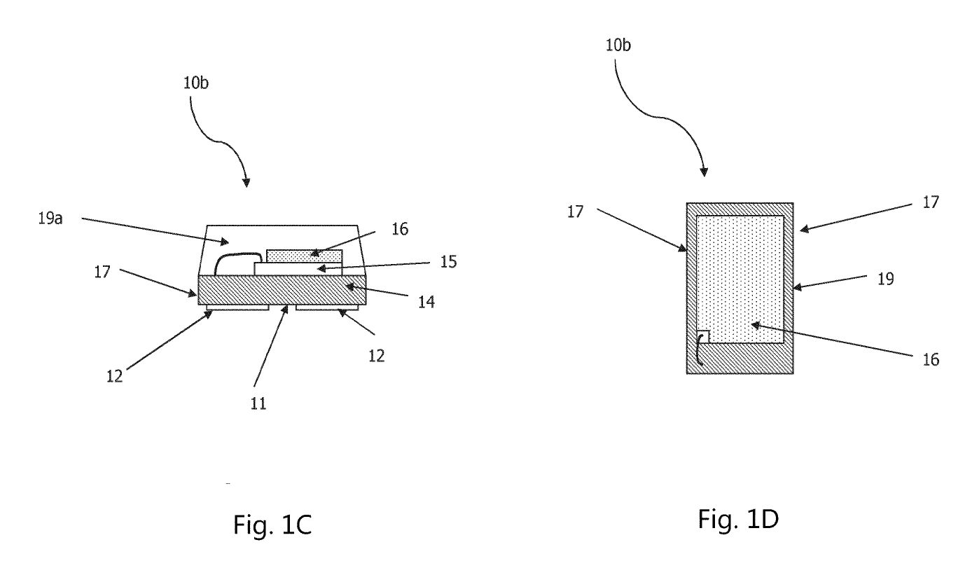

FIG. 1A and FIG. 1B are schematic representations of a first electrical component 10a. The first electrical component 10a may be a discrete component. The first electrical component 10a may be intended for being arranged as a single component on a circuit carrier, such as for example a printed circuit board (PCB) or an aluminum metal-core printed circuit board. An electrical subassembly may include a circuit carrier, on which a large number of different electrical components are arranged, the electrical components being connected to one another by way of electrical conductors. Often, a certain functionality is provided by a subassembly. The electrical component 10 may be a surface mounted component (surface mounted device, SMD), which can be electrically and mechanically connected to a printed circuit board by soldering or adhesive bonding. The component 10 may have a generic component form.

The proposed solution is explained below by the example of a light-emitting diode (LED), it being possible for the features that are explained in connection with an LED also to be provided in the case of other electrical components, such as for example resistors, capacitors, laser diodes, sensors, etc.

The component 10 includes an underside 11. Arranged on the underside 11 of the component 10 are at least two electrical terminal contacts 12, the two electrical terminal contacts 12 respectively forming the positive pole and the negative pole of the electrical component 10. The component 10 is designed for being placed with the electrical terminal contacts 12 that are arranged on the underside 11 onto electrical terminal contacts of a circuit carrier. The electrical terminal contacts 12 are also designed for being connected in a mechanical and electrically conducting manner to terminal contacts of the circuit carrier by adhesive bonding and/or soldering. The electrical terminal contacts may for example have a special surface coating and/or have solder beads 13 (solder balls) attached to the electrical terminal contacts 12. Apart from the electrical terminal contacts 12 intended for the electrical contacting of the component 10, further terminal contacts may optionally be provided. The additional terminal contacts may be intended for the mechanical, electrical and/or thermal attachment of the component 10.

The electrical component 10 schematically represented in FIG. 1A and FIG. 1B includes a leadframe. As an alternative or in addition to a leadframe, substrates of semiconductor material or ceramic may also be provided. The leadframe may be formed from a stamped or etched metal sheet. In the case of the embodiment of FIG. 1B, represented in a simplified form, the underside of the leadframe forms the electrical terminal contacts 12. Arranged on the upper side of the leadframe is a light-emitting chip 15. In addition, the component 10 may contain a phosphor 16, which is arranged downstream of the chip 15 in the radiating direction. The phosphor 16 is designed for converting the electromagnetic radiation emitted by the chip 15 in a first wavelength range at least partially into a second wavelength range. The electromagnetic radiation emitted by the component may for example be perceived by a viewer as white light or monochrome light. Moreover, the component 10 has potting material 18. The potting material 18 may for example be designed for reflecting the electromagnetic radiation emitted by the component. The component 10 also has a housing 19. The housing 19 may for example include a plastics material. The plastics material of the housing 19 may be electrically insulating.

In FIG. 1C, a second component 10b is represented. The second component 10b differs from the first component 10a in particular in that the chip is arranged on a substrate 14. The substrate 14 may for example be a ceramic containing aluminum nitride or a semiconductor material containing silicon. Arranged on the substrate 14 is the chip 15. The chip 15 and the substrate 14 may be covered by a covering 19a. The covering 19a may for example be formed from a transparent material, such as for example silicone. In the case of further components, the covering 19a may also be formed from a reflective material, such as for example titanium dioxide. If a reflective covering is provided, the upper side of the chip 15 or possibly of the phosphor 16 is exposed. Arranged on the underside of the substrate 14 are the electrical terminal contacts 12 of the component.

The first and second electrical components 10a, 10b have side regions 17. The side regions 17 represented adjoin the underside 11 of the component 10. The side regions 17 are arranged substantially perpendicularly to the underside 11. Depending on the form of the component, the side regions 17 may however also be sloping, curved and/or stepped. The term side regions generally denotes the regions of a component that are facing other, laterally adjacent components in the installed state. In the case of the embodiment of FIGS. 1A and 1B, the side regions 17 are formed by a side face of the housing 19. In the case of the embodiment of FIG. 1C, the side regions are formed partly by the substrate 14 and partly by the covering 19a. The side region 17 can also furthermore be completely formed by the covering 19a. This may be the case for example whenever the covering 19a covers the side faces of the substrate 14.

Adhesive regions may be provided on the side regions 17. The adhesive regions may be designed for entering into a material-bonded connection with an adhesive 22. Adhesive regions may for example be provided whenever the housing 19 of a component is formed from a material that does not enter into a connection with the adhesive 22 or the adhesive 22 is only to be applied at points intended for it. For example, an exposed side face of the substrate 14 may be provided as an adhesive region. The adhesive 22 may only be applied to the side faces of the substrate 14. The side faces of the covering 19a may remain substantially free from adhesive 22.

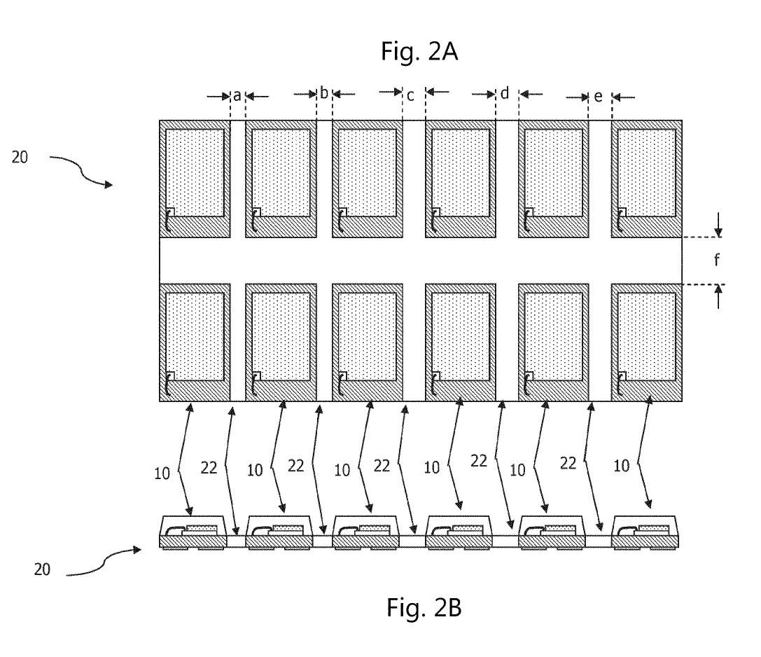

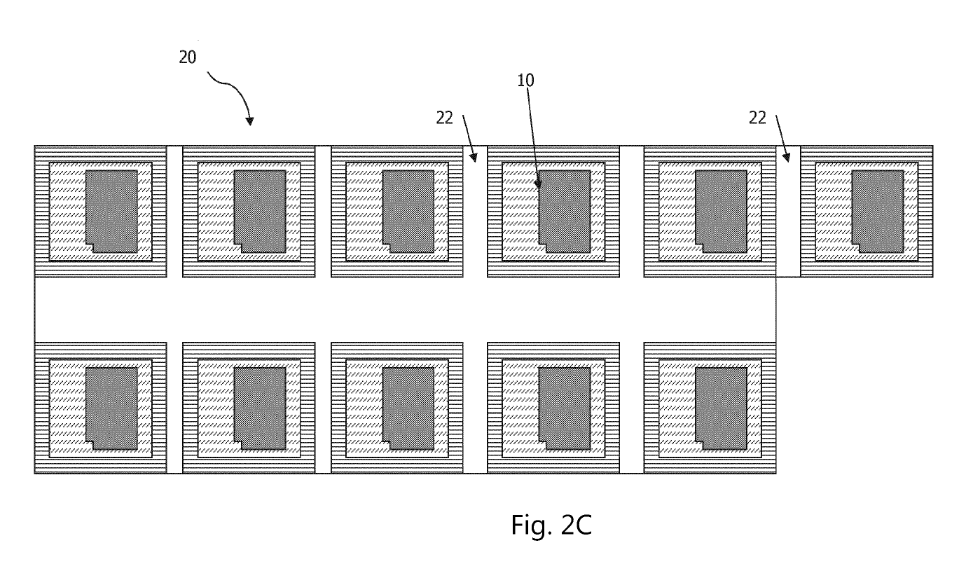

In FIG. 2A and FIG. 2B, a component arrangement 20 is represented. The component arrangement 20 may for example include twelve of the components 10 described in conjunction with FIGS. 1A-1D. The components are arranged in a 2×6 matrix. Generally, the component arrangement 20 may include two or more components. As a difference from a multi-chip component, in the case of which a number of light-emitting chips are combined in a common housing or on a common substrate, in the component arrangement 20 individual components respectively with a light-emitting chip 15 are combined. The individual components 10 of the component arrangement 20 respectively have separate housings 19 or substrates 14. Components that can also be processed individually as surface-mountable components are combined to form a component arrangement. In order to be able to provide particularly compact component arrangements 20, components 10 that have smallest possible lateral dimensions can be selected for the component arrangement 20.

In the component arrangement 20, the components 10 are arranged in a product configuration. The product configuration corresponds to an arrangement of the components 10 in an end product. The spacings of the components 10 in the product configuration correspond to the spacings of the components 10 in the end product. In the product configuration, the components 10 of the component arrangement 20 may be arranged with closer positional tolerances than separately inserted components. Since the component arrangement 20 has a large number of terminal contacts 12, self-centering effects can additionally increase the positional accuracy of the component arrangement 20 on the circuit carrier. The spacings and the positional tolerances with which the components 10 can be provided in the component arrangement 20 depend for example on the number of components 10 that are combined in the component arrangement 20. Thus, component arrangements with for example 1×2 components or with 2×2 components may be provided with smaller spacings and closer tolerances than component arrangements with for example 2×10 components. For example, minimum spacings of 10 μm can be realized for component arrangements with 1×2 components, whereas minimum spacings of 50 μm can be realized for component arrangements with for example 2×10 components. The positional tolerances may for example be +/−15 pm for component arrangements with 2×10 components.

Adhesive 22 is arranged between adjacent components 10 of the component arrangement 20. The adhesive 22 mechanically connects adjacent components 10 of the component arrangement 20 to one another. The adhesive 22 is arranged between the side regions 17 of the components 10. The adhesive 22 may wet the entire side regions 17 of a component 10 or, as indicated in FIG. 2B or FIG. 4, only an adhesive region provided on the side region 17. In the case of the embodiment represented in FIG. 2B, the adhesive 22 is for example arranged on exposed sides of the substrate 14. The components 10 fabricated in the component arrangement 20 are rigidly connected to one another by the adhesive 22. The rigid connection between the components 10 allows the component arrangement 20 to be handled like a single component. The spacings a, b, c, d, e, f between the individual components 10 are fixed by the adhesive 22. On the underside 11, the electrical terminal contacts 12 of the individual components 10 are freely accessible. The upper side of the component arrangement is freely accessible.

In FIG. 2A and FIG. 2B, the component arrangement 20 is represented in the uninstalled state, that is to say before the component arrangement 20 is fastened onto a circuit carrier. In the uninstalled state, the adhesive 22 is rigid. The adhesive 22 may be chosen such that the modulus of elasticity of the adhesive 22 in the uninstalled state is so great that the forces and/or accelerations occurring during the processing of the component arrangement 20, for example when picking up the component arrangement with an insertion head of a component insertion machine, do not bring about any evident deformation of the adhesive 22 and/or of the component arrangement. A movement of the components 10 of the component arrangement 20 in relation to one another is not possible. The adhesive 22 may also be chosen such that, at least in the installed state of the component arrangement, the modulus of elasticity of the adhesive 22 is less than the modulus of elasticity of a single component 10. The modulus of elasticity of a component 10 may depend in particular on the modulus of elasticity of a leadframe or substrate contained in the component 10. Correspondingly, the adhesive 22 may be chosen such that the modulus of elasticity of the adhesive 22 is less than the modulus of elasticity of a leadframe or of a substrate.

The components 10 may be packed in the component arrangement 20 relatively densely. For example, the spacing a, b, c, d, e, f between the edges of two adjacently arranged components may be between 200 μm and 10 μm. The spacings between the components 10 of the component arrangement may be identical or different. For example, the spacings in the case of the embodiment represented in FIG. 2A are a=50 μm, b=50 μm, c=75 μm, d=75 μm, e=75 μm and f=100 μm. The spacings between the individual components of the component arrangement are made to match the spacings of the solder pads on the circuit carrier. Production tolerances of individual components 10 can be compensated by the adhesive 22. For example, a thicker layer of the adhesive 22 may be arranged in the lateral direction between two components 10 of which the lateral dimensions respectively lie at a lower tolerance limit than between two components 10 of which the dimensions lie at an upper tolerance limit.

The adhesive 22 may be electrically insulating. The adhesive 22 may also be chosen such that, after applying the component arrangement 20 to a circuit carrier, the adhesive 22 becomes flexible and/or can be removed by a certain treatment. For example, the adhesive may be chosen such that, after applying the component arrangement 20 to a circuit carrier, the adhesive 22 can be removed again by washing the circuit carrier and the applied component arrangement. An isopropanol solution may be provided for example for the washing of the circuit carrier. However, an adhesive 22 that is at least partially decomposed or becomes flexible under the effect of temperature may also be used. For example, an adhesive 22 that partially decomposes already during a reflow soldering that is provided for connecting the components of the component arrangement to the circuit carrier may be used. For example, the adhesive 22 may at least partially evaporate during the soldering. A hotmelt adhesive that becomes soft when heated may also be used for example.

In comparison with multi-chip components, the mechanical loading of the soldered or adhesively bonded connections of the components can be reduced by the component arrangement. This may be the case for example whenever the multi-chip components have ceramic or semiconductor substrates of which the coefficients of thermal expansion differ considerably from the coefficients of thermal expansion of the metals contained in the circuit carrier, such as for example copper or aluminum. For example, when there are changes in temperature, the different coefficients of expansion of the component 10 and of a circuit carrier can cause mechanical stresses. In particular in the case of large components, mechanical stresses caused in this way may lead to destruction of the electrical connection between the component and the circuit carrier and consequently to failure of the component or the entire subassembly. In the case of the component arrangement, the adhesive 22 arranged between the components 10 may act as a buffer and take up some of the mechanical stresses. The adhesive 22 may also furthermore be provided as a predetermined breaking point, since destruction of the adhesive 22 has no effects, or at most only minor effects, on the function of the end product.

The subsequent removal of the adhesive 22 or the use of an adhesive 22 that becomes flexible allows the mechanical loads of the connections between the individual components and the circuit carrier and resultant problems of reliability to be reduced. If the adhesive 22 is removed after the application of the component arrangement 20, the individual components 10 of the component arrangement are then only connected to one another by way of the circuit carrier. The mechanical stresses occurring as a result of the different coefficients of thermal expansion cannot be transferred from one component to another component, so that only small mechanical stresses occur. If an adhesive that becomes flexible in the installed state as a result of a corresponding treatment or on the basis of its properties is used, the flexible adhesive 22 can take up some of the mechanical stresses. Correspondingly, the mechanical loading of the connections between the component and the circuit carrier is less.

The components 10 of the component arrangement 20 may be identical and/or different components. Components of different component types may also furthermore be combined to form a component arrangement 20. For example, the components 10 of the component arrangement 20 may be in each case LEDs with the same optical and electrical properties. In a further embodiment, the components 10 of the component arrangement 20 may be in each case LEDs with different optical properties. For example, “white LEDs” and/or “colored LEDs” of different colors of light may be combined in the component arrangement. In further embodiments, the component arrangement may include optoelectronic sensors, electrical resistors, capacitors, etc. The component arrangement may exclusively contain optoelectronic components. Components of which the position in the end product is relevant for the function of the end product may also be combined in the component arrangement. This may be the case for example in particular for optoelectronic components of which the arrangement in relation to optical elements arranged in the path of rays is relevant for the function of the end product. In the case of purely electrical components, such as for example resistors and capacitors, the exact position of the components in the end product is generally not relevant, since the function of these components is substantially independent of their arrangement on the circuit carrier.

The form of the component arrangement 20 may be chosen such that the alignment of the component arrangement 20 is clearly evident. This may be achieved for example by an unsymmetrical form of the component arrangement 20. This allows for example polarity reversal protection to be provided. The component arrangement 20 can also be prevented from being turned by 180° when it is applied to a circuit carrier. A corresponding arrangement is represented for example in FIG. 2C. As an alternative or in addition to an unsymmetrical form, marking elements, such as for example recesses and/or projections, may also be provided.

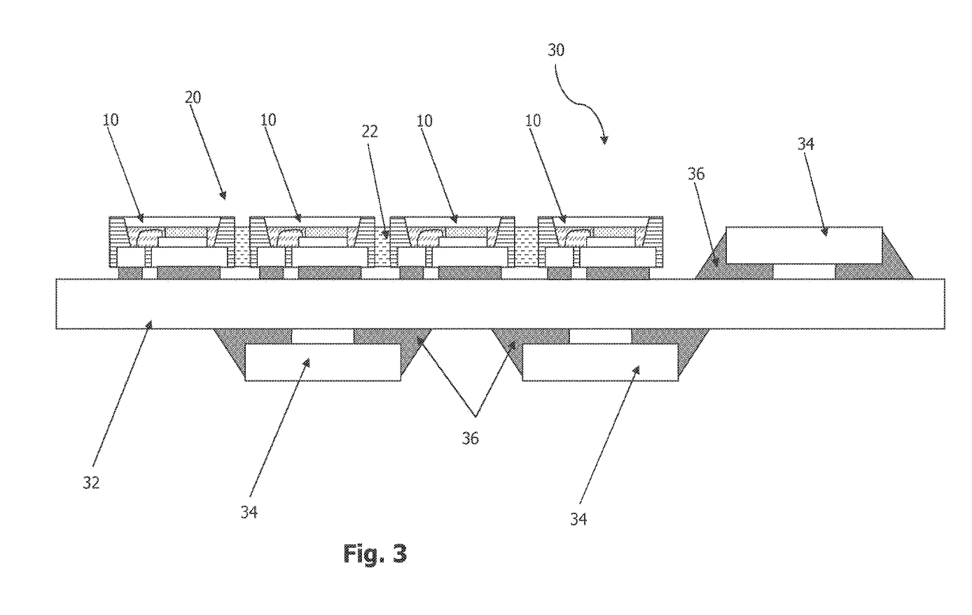

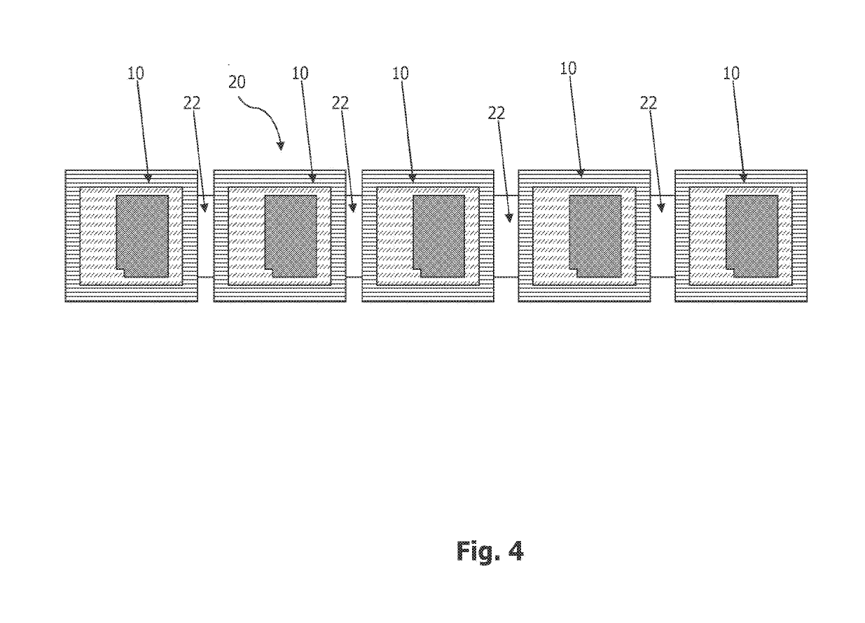

In FIG. 3, a cross section through an assembled subassembly is schematically indicated. The subassembly 30 includes a circuit carrier 32, a component arrangement 20 and further components 34. The components are connected to the circuit carrier 32 by soldered connections 36. Depending on the functionality of the subassembly, the further components 34 may be for example resistors; capacitors, diodes, integrated circuits, transistors, etc. In the case of the representation of FIG. 3, components are arranged on both sides of the circuit carrier. Depending on the respective application and/or type of the circuit carrier, the components may also be arranged only on one side of the circuit carrier 32.

The electrical components 10 of the component arrangement 20 are connected to the circuit carrier 32 by separate connections. The components are connected to the circuit carrier by at least two electrical connections. In this way, the individual components 10 of the component arrangement 20 can be activated independently of one another. There is no direct electrical connection between the components 10 of the component arrangement 20.

In the installed state of the component arrangement 20, the modulus of elasticity of the adhesive 22 may be less than in the uninstalled state of the component arrangement 20. This is indicated in FIG. 3 by the adhesive 22 represented by dashed lines. For example, the modulus of elasticity of the adhesive may be reduced by a thermal treatment. Moreover, the adhesive 22 may be at least partially removed.

FIG. 4 is a schematic representation of a plan view of an embodiment. The embodiment represented in FIG. 4 may correspond substantially to the embodiments represented in FIGS. 2A-2C and 3, the components 10 of the component arrangement being arranged as a 1×5 matrix. In the case of the representation of FIG. 4, the adhesive 22 has been introduced between the components at an adhesive region respectively arranged in the middle of the side face. Since the form of the component arrangement is determined by the desired arrangement of the components in an end product, the components in the component arrangement may be arranged in a large number of different forms.

In one specific embodiment, the component arrangement 20 may be intended for a headlamp or a tail lamp of a vehicle. The corresponding component arrangement 20 may for example include LED components that emit white light, orange light and/or red light. The component arrangement may also include optical sensors, temperature-dependent resistors, coding resistors and/or activation components. The components of the component arrangement 20 may for example be fabricated by a component manufacturer in a product configuration prescribed by the customer, for example a manufacturer of the headlamp or of the tail lamp. The components 10 of the component arrangement may be intended for providing different light functions of the headlamp or the tail lamp. For example, the components of the component arrangement may provide light for a daytime-running-light, low-beam, high-beam, turn-indicator and/or cornering-light function of a headlamp. A large number of LEDs with small spacings can be provided in the component arrangement. This facilitates the implementation of additional light functions. For example, the component arrangement may be intended for arranging the LEDs for an adaptive low-beam light and/or a so-called matrix headlamp with small spacings in relation to one another and with close positional tolerances on a circuit carrier of the headlamp. The component arrangement is generally suitable for functions that require a high packing density of the components. In further embodiments, the components 10 of the component arrangement 20 may provide light for a brake-light, turn-indicator, reversing-light and/or rear-fog-lamp function of a tail lamp. By means of the component arrangement described, the manufacturer of the headlamp or the tail lamp can easily handle the LED components that are required for providing the different light functions. The component arrangement 20 also requires relatively little space on the circuit carrier of the headlamp or tail-lamp subassembly.

For producing the component arrangement described above, a large number of components 10 and a processing carrier are provided. The processing carrier may for example be formed from a metal or semiconductor material. The processing carrier is intended for provisionally receiving the components. An adhesive layer is arranged on the processing carrier. The adhesive layer may for example be a double-sided adhesive film. At least one adhesive side of the adhesive film may be designed for allowing the adhesive effect to be reduced, for example by the effects of temperature. This allows the subsequent removal of the component arrangement from the adhesive layer of the processing carrier to be facilitated.

The components 10 provided are applied to the adhesive layer. Devices that are intended for the positioning of singulated chips in semiconductor production may be provided for example for applying the components. The components 10 may be applied with their underside to the adhesive layer. The large number of components 10 are applied to the processing carrier in a product configuration. The adhesive layer has the effect of fixing the components 10 on the processing carrier.

After or during the application of the components to the processing carrier, adhesive 22 may be introduced between two adjacently arranged components 10, for example by dispensing. In this case, capillary effects may promote a uniform distribution of the adhesive 22 between the components 10. The components can be mechanically connected to one another by the adhesive 22 that is introduced. As an alternative to the dispensing of an adhesive, the components may be re-formed with adhesive. For the re-forming, the components arranged on the processing carrier may for example be arranged in a mold tool. The adhesive may then be forced into the mold. In this case, the mold of the tool may be designed such that the upper side and the underside of the components are not involved in the re-forming. As an alternative, the upper side of the components may for example be exposed again after the re-forming by being ground away.

After the curing of the adhesive 22, the component arrangement may be removed from the carrier. Optionally, after the removal of the component arrangement 20, solder beads may be attached to the terminal contacts 12 of the components 10. The component arrangement may then be placed in a transport packaging. The transport packaging with the components may for example be provided for a manufacturer of subassemblies for further processing.

The component arrangement and the method for producing a component arrangement have been described on the basis of several embodiments for the purpose of illustrating the underlying concept. The embodiments are not restricted here to specific combinations of features. Even if some features and refinements have only been described in connection with a particular embodiment or individual embodiments, they can in each case be combined with other features from other embodiments. It is similarly possible to omit or add individual presented features or particular refinements in embodiments, as long as the general technical teaching continues to be realized.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A component arrangement with at least two electrical components arranged next to one another in a product configuration, each of the electrical components having at least two electrical terminal contacts and the components arranged next to one another being mechanically connected to one another by an adhesive arranged between the components, and the component arrangement being designed for the individual components of the component arrangement to be applied together to a circuit carrier.

2. The component arrangement as claimed in claim 1, the at least two electrical components being optoelectronic components that are designed for emitting electromagnetic radiation.

3. The component arrangement as claimed in claim 1, the component arrangement having at least two identical components and/or two different components.

4. The component arrangement as claimed in claim 1, the adhesive being electrically insulating.

5. The component arrangement as claimed in claim 1, the product configuration corresponding to the arrangement of the at least two electrical components in an end product.

6. The component arrangement as claimed in claim 1, solder beads being arranged at the electrical terminal contacts.

7. The component arrangement as claimed in claim 1, the electrical components respectively having a single light-emitting chip.

8. The component arrangement as claimed in claim 1, the electrical components of the component arrangement being designed for being activated independently of one another.

9. The component arrangement as claimed in claim 1, the adhesive between the electrical components being designed for being removed after the application of the component arrangement to a circuit carrier.

10. The component arrangement as claimed in claim 1, the mechanical strength of the adhesive being less in the installed state than in the uninstalled state and/or the mechanical strength of the adhesive in the installed state being less than the mechanical strength of the components.

11. The component arrangement as claimed in claim 1, the spacing between two adjacent electrical components of a component arrangement being less than 200 μm.

12. The component arrangement as claimed in claim 11, the spacing between two adjacent electrical components of a component arrangement being less than 100 μm.

13. The component arrangement as claimed in claim 1, the components having in a direction parallel to the underside of the components a maximum deviation from their desired position of less than 50 μm.

14. A lamp for a land vehicle in which at least some of the light functions are provided by a component arrangement
the component arrangement with at least two electrical components arranged next to one another in a product configuration, each of the electrical components having at least two electrical terminal contacts and the components arranged next to one another being mechanically connected to one another by an adhesive arranged between the components, and the component arrangement being designed for the individual components of the component arrangement to be applied together to a circuit carrier.

15. A method for producing a component arrangement, comprising:
providing at least two electrical components,
providing a processing carrier having an adhesive layer, arranging the at least two electrical components on the adhesive layer of the processing carrier in a product configuration,
mechanically connecting the at least two electrical components with an adhesive,
removing the component arrangement from the processing carrier, and
packing the component arrangement in a transport packaging.

16. The method for producing a component arrangement as claimed in claim 15, the adhesive being introduced between the components by dispensing.

17. The method for producing a component arrangement as claimed in claim 15, solder beads being attached to terminal contacts of the components after the removal of the component arrangement from the processing carrier.
